(19) United States
(12) Patent Application Publication
(10) Pub. No.: US 2026/0040440 A1
(43) Pub. Date: Feb. 5, 2026

(54) PRINTED CIRCUIT BOARD

(71) Applicant: SAMSUNG ELECTRO-MECHANICS CO., LTD., Suwon-si (KR)

(72) Inventors: Chang Hwa PARK, Suwon-si (KR); Sang Yun LEE, Suwon-si (KR); Sang Ho JEONG, Suwon-si (KR); Hyun Hu LEE, Suwon-si (KR)

(73) Assignee: SAMSUNG ELECTRO-MECHANICS CO., LTD., Suwon-si (KR)

(21) Appl. No.: 19/176,411

(22) Filed: Apr. 11, 2025

(30) Foreign Application Priority Data
Aug. 1, 2024 (KR) 10-2024-0102580

(51) Int. Cl. H05K 1/02; H05K 1/11

(52) U.S. Cl. CPC H05K 1/0298; H05K 1/115; H05K 2201/0175; H05K 2201/0195

(57) ABSTRACT

A printed circuit board including: a first conductor pattern; a first insulating film covering at least a portion of the first conductor pattern conforming to a shape of a surface of the first conductor pattern; and an insulating layer disposed on the first insulating film, the first insulating film including a first inorganic layer and a first organic layer.

### CROSS-REFERENCE TO RELATED APPLICATION(S)

This application claims benefit of priority to Korean Patent Application No. 10-2024-0102580 filed on Aug. 1, 2024, in the Korean Intellectual Property Office, the disclosure of which is incorporated herein by reference in its entirety.

### TECHNICAL FIELD

The present disclosure relates to a printed circuit board.

Recently, a thickness of an insulation layer has been continuously reduced to form microcircuits and microvias, and as a result, the influence of foreign substances/scratches/scratches, or the like, has increased, which may cause interlayer short circuits or migration problems between circuits.

### SUMMARY

An aspect of the present disclosure is to provide a printed circuit board that may secure adhesion between a conductor pattern and an insulating layer.

Another aspect of the present disclosure is to provide a printed circuit board that may improve signal loss through a non-roughness surface.

Yet another aspect of the present disclosure is to provide a printed circuit board that may improve interlayer short circuits or migration due to foreign substances/damage/scratches, or the like.

One of the various solutions provided by the present disclosure is to provide a printed circuit board in which a conductor pattern is embedded in an insulating layer, thereby forming an insulating film including an inorganic layer and an organic layer on a surface of a conductor pattern.

For example, a printed circuit board may include: a first conductor pattern; a first insulating film covering at least a portion of the first conductor pattern and conforming to a shape of a surface of the first conductor pattern; and an insulating layer disposed on the first insulating film, and the first insulating film may include a first inorganic layer and a first organic layer.

One of the various solutions provided by the present disclosure is to provide a printed circuit board in which a conductor pattern is embedded in a plurality of insulating layers, thereby forming an insulating film not only on a surface of a conductor pattern but also between a plurality of insulating layers.

For example, a printed circuit board may include: a first insulating layer; a first conductor pattern embedded in a first side of the first insulating layer, wherein at least a portion of a first surface of the first conductor pattern is exposed from a first surface of the first insulating layer; a first insulating film covering at least a portion of each of a second surface and a side surface of the first conductor pattern and conforming to a shape of the first conductor pattern, and extending onto the first surface of the first insulating layer; a second insulating layer disposed on a second surface of the first insulating layer; a second insulating film disposed between the first and second insulating layers and having a thickness thinner than each of the first and second insulating layers; and a second conductor pattern disposed on a first surface of the second insulating layer.

One of the various effects of the present disclosure is to provide a printed circuit board that may secure adhesion between a conductor pattern and an insulating layer.

Another of the various effects of the present disclosure is to a printed circuit board that may improve signal loss through a non-roughness surface treatment.

Yet another of the various effects of the present disclosure is to provide a printed circuit board that may improve interlayer short circuits or migration due to foreign substances/damage/scratches, or the like.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is a schematic enlarged cross-sectional view of region A of the printed circuit board of FIG. 3;

FIG. 5 is a schematic process cross-sectional view according to an example of manufacturing the printed circuit board of FIG. 3;

FIG. 6 is a cross-sectional view schematically illustrating another example of a printed circuit board;

FIG. 7 is a schematic enlarged cross-sectional view of region B of the printed circuit board of FIG. 6;

FIG. 8 is a schematic process cross-sectional view according to an example of manufacturing the printed circuit board of FIG. 6;

FIG. 9 is a cross-sectional view schematically illustrating another example of a printed circuit board;

FIG. 10 is a schematic enlarged cross-sectional view of region C of the printed circuit board of FIG. 9;

FIG. 11 is a schematic process cross-sectional view according to an example of manufacturing the printed circuit board of FIG. 9;

FIG. 12 is a cross-sectional image diagram schematically illustrating a layer structure of an insulating film formed between a conductor pattern and an insulating material;

FIG. 13 is a cross-sectional view schematically illustrating an example of a semiconductor package; and

FIG. 14 is a cross-sectional view schematically illustrating another example of a semiconductor package.

### DETAILED DESCRIPTION

Hereinafter, the present disclosure will be described with reference to the accompanying drawings. In the drawings, the shape and size of the elements may be exaggerated or reduced for clearer description.

### Electronic Device

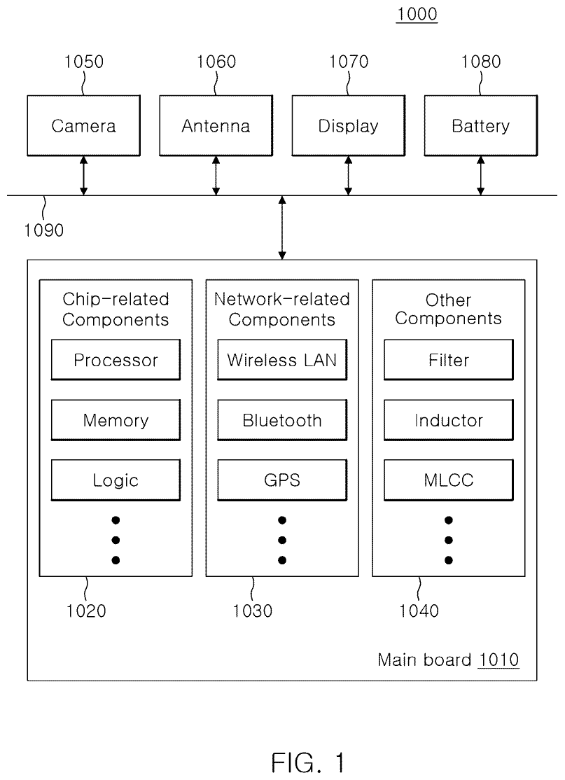

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

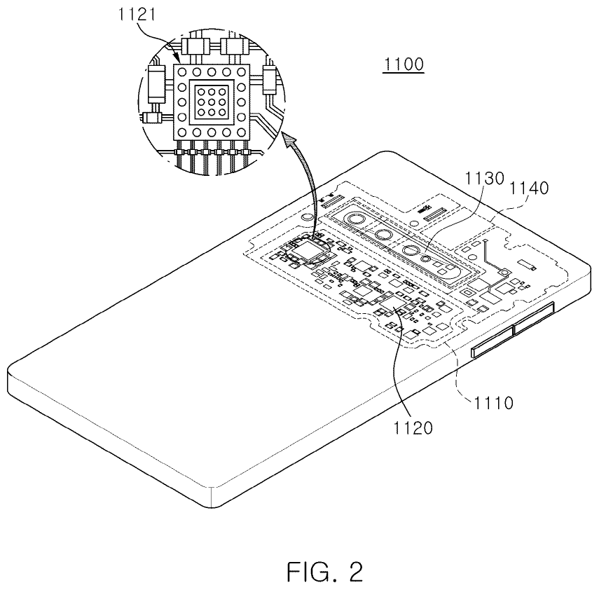

FIG. 2 is a perspective view schematically illustrating an example of an electronic device.

Referring to FIG. 2, an electronic device may be, for example, a smartphone 1100. A mother board 1110 may be accommodated in the smartphone 1100, and various components 1120 may be physically and/or electrically connected to the mother board 1110. Furthermore, other components that may or may not be physically and/or electrically connected to the mother board 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may have the form of a printed circuit board in which an electronic component including an active component and/or a passive component is mounted on a surface. Alternatively, the component package 1121 may have the form of a printed circuit board in which an active component and/or a passive component are embedded. On the other hand, the electronic device is not necessarily limited to the smartphone 1100, and may be other electronic devices as described above.

### Printed Circuit Board

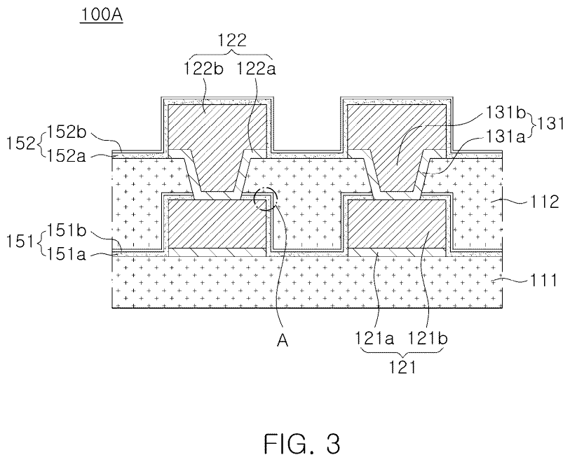

FIG. 3 is a cross-sectional view schematically illustrating an example of a printed circuit board.

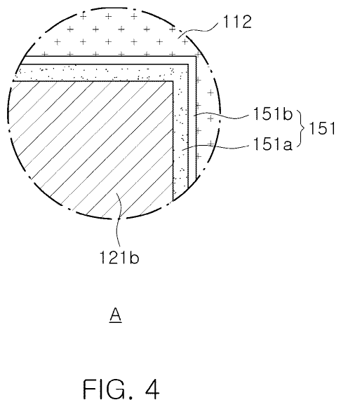

FIG. 4 is a schematic enlarged cross-sectional view of region A of the printed circuit board of FIG. 3.

Referring to the drawings, a printed circuit board 100A according to an example embodiment may include: a first insulating layer 111, a first conductor pattern 121 disposed on an upper surface of the first insulating layer 111, a second insulating layer 112 disposed on the upper surface of the first insulating layer 111 and filling the first conductor pattern 121, a second conductor pattern 122 disposed on an upper surface of the second insulating layer 112, a first insulating film 151 covering at least portions of each of an upper surface and a side surface of the first conductor pattern 121 and extending onto a lower surface (first surface) of the second insulating layer 112, a second insulating film 152 covering at least portions of each of an upper surface (first surface) and a side surface of the second conductor pattern 122 and extending onto the upper surface of the second insulating layer 112, and a via pattern 131 penetrating through the second insulating layer 112 and the first insulating film 151 and configured to connect the first and second conductor patterns 121 and 122 to each other. The first and second conductor patterns 121 and 122 and the via pattern 131 may be provided in plural.

In this case, at least a portion of the first insulating film 151 may be disposed between the first conductor pattern 121 and the second insulating layer 112. For example, the first insulating film 151 may cover at least a portion of the first conductor pattern 121 conforming to a shape of a surface of the first conductor pattern 121. For example, the first insulating film 151 may be conformally disposed on the first conductor pattern 121 and may extend onto the lower surface of the second insulating layer 112. When there are a plurality of first conductor patterns 121, the first insulating film 151 may be continuously disposed on the lower surface of the second insulating layer 112 between the plurality of first conductor patterns 121. The first insulating film 151 may be formed of a plurality of layers, and may include, for example, a first inorganic layer 151a and a first organic layer 151b. On the surface of the first conductor pattern 121, the first inorganic layer 151a may be in contact with the first conductor pattern 121, and the first organic layer 151b may be in contact with the second insulating layer 112.

In this manner, in the printed circuit board 100A according to an example embodiment, the surface of the first conductor pattern 121 may be covered with the first insulating film 151. In this case, the first insulating film 151 may be formed by dry surface treatment as described below, and may include the first inorganic layer 151a and the first organic layer 151b. Accordingly, sufficient adhesion with the second insulating layer 112 may be secured even without wet surface treatment such as CZ treatment, and signal loss may be effectively improved by lowering surface roughness. Additionally, design margin may be sufficiently secured by undergoing a non-etching process. Additionally, interlayer short circuits due to foreign substances/damage/scratches, or migration/spark/shorts between the plurality of first conductor patterns 121 may be effectively improved through the first insulating film 151 including the first inorganic layer 151a and the first organic layer 151b disposed in the above-described form. For example, even when a thickness of the second insulating layer 112 is as thin as 10 μm or less, the above-described problems may be effectively improved. Accordingly, a yield thereof may be improved.

Meanwhile, when the first insulating film 151 includes only the first inorganic layer 151a, problems such as voids and peeling may occur at an interface with the second insulating layer 112. Additionally, when the first insulating film 151 includes only the first organic layer 151b, it may be difficult to improve interlayer short circuits due to foreign substances/damage/scratches or the like, or migration/spark/shorts.

Meanwhile, in the first insulating film 151, the first inorganic layer 151a may be thicker than the first organic layer 151b. For example, the first inorganic layer 151a may have a thickness of about 1 nm to 50 nm or about 5 nm to 30 nm, and the first organic layer 151b may have a thickness of about 0.1 nm to 10 nm or about 0.5 nm to 5 nm. When a thickness thereof is not constant, the thickness here may be an average thickness, and for example, may be an average value of thickness values measured at five arbitrary points based on a cross-sectional image photograph of the first insulating film 151 including the first inorganic layer 151a and the first organic layer 151b. The cross-sectional image photograph may be captured by Transmission Electron Microscopy (TEM), or the like.

In the thickness relationship, the above-described effect by the first insulating film 151 may be more excellent.

Additionally, in the first insulating film 151, the first inorganic layer 151a may include a metal oxide, a nitride, or both and the first organic layer 151b may include a silane compound. The metal oxide may include, for example, Al₂O₃, TiO₂, and/or TaO₂, the nitride may include SiNₓ, and the metal oxide may preferably include Al₂O₃, but the present disclosure is not limited thereto. The silane compound may include, for example, an amino silane compound and/or an imidazole silane compound, and may include, preferably, an amino silane compound, such as 3-Aminopropyltriethoxysilane (APTES), but the present disclosure is not limited thereto. A material of the first organic layer 151b may be analyzed using X-ray Photoelectron Spectroscopy (XPS), but the present disclosure is not limited thereto. Through such material selection, the above-described effect by the first insulating film 151 may be more excellent.

Meanwhile, at portion of the second insulating film 152 may be disposed on the second conductor pattern 122. For example, the second insulating film 152 may cover at least a portion of the second conductor pattern 122 conforming to a shape of the surface of the second conductor pattern 122. For example, the second insulating film 152 may be conformally disposed on the second conductor pattern 122, and may extend onto the upper surface of the second insulating layer 112. When there are a plurality of second conductor patterns 122, the second insulating film 152 may be continuously disposed on the upper surface of the second insulating layer 112 between the plurality of second conductor patterns 122. The second insulating film 152 may include a second inorganic layer 152a and/or a second organic layer 152b. The second insulating film 152 may also be formed of a plurality of layers, and may include, for example, the second inorganic layer 152a and the second organic layer 152b substantially the same as the first insulating film 151. On the surface of the second conductor pattern 122, the second inorganic layer 152a may be in contact with the second conductor pattern 122, and the second organic layer 152b may be spaced apart from the second conductor pattern 122. Through the second insulating film 152, the technical effect described in the first insulating film 151 described above may be similarly implemented.

Meanwhile, the second inorganic layer 152a may be thicker than the second organic layer 152b. For example, the second inorganic layer 152a may have a thickness of about 1 nm to 50 nm or about 5 nm to 30 nm, and the second organic layer 152b may have a thickness of about 0.1 nm to 10 nm or about 0.5 nm to 5 nm. When a thickness thereof is not constant, the thickness here may be an average thickness, and may be, for example, an average value of thickness values measured at five arbitrary points based on a cross-sectional image photograph of the second insulating film 152 including the second inorganic layer 152a and the second organic layer 152b. The cross-sectional image photograph may be captured by Transmission Electron Microscopy (TEM), or the like. In the thickness relationship, the above-described effect by the second insulating film 152 may be more excellent.

Additionally, the second inorganic layer 152a may include a metal oxide, a nitride, or both, and the second organic layer 152b may include a silane compound. The metal oxide may include, for example, Al₂O₃, TiO₂, and/or TaO₂, the nitride may include SiNₓ, and the metal oxide may include, preferably, Al₂O₃, but the present disclosure is not limited thereto. The silane compound may include, for example, an amino silane compound and/or an imidazole silane compound, and it may preferably include an amino silane compound, such as APTES (3-Aminopropyltriethoxysilane), but is not limited thereto. The material of the second organic layer 152b may be analyzed using XPS (X-ray Photoelectron Spectroscopy), but is not limited thereto. Through such material selection, the above-described effect by the second insulating film 152 may be more excellent.

Hereinafter, components of a printed circuit board 100A according to an example embodiment will be described in more detail with reference to the drawings.

Each of the first and second insulating layers 111 and 112 may include an insulating material. The insulating material may include an organic insulating material. The organic insulating material may include a thermosetting resin such as an epoxy resin, a thermoplastic resin such as a polyimide, or a material including an inorganic filler, an organic filler, and/or glass fiber (Glass Fiber, Glass Cloth or Glass Fabric) together with the resin. For example, the organic insulating material may be a non-photosensitive insulating material such as Copper Clad Laminate (CCL), an Ajinomoto Build-up Film (ABF), Prepreg (PPG), but the present disclosure is not limited thereto, and other polymer materials may be used in addition thereto. Additionally, the organic insulating material may be a photosensitive insulating material such as Photoimageable Dielectric (PID). Preferably, each of the first and second insulating layers 111 and 112 may be the ABF, and ABFs having various compositions such as, ABF having a low coefficient of thermal expansion (Low CTE), ABF including a nano filler, and ABF having a low dielectric constant (Low Df), may be used. If necessary, the first insulating layer 111 may be omitted, but the present disclosure is not limited thereto.

Each of the first and second conductor patterns 121 and 122 may include a metal material. The metal material may include copper (Cu), aluminum (Al), silver (Ag), tin (Sn), gold (Au), nickel (Ni), lead (Pb), titanium (Ti), and/or alloys thereof. The metal material may include, preferably, copper (Cu), but is not limited thereto. Each of the first and second conductor patterns 121 and 122 may include a signal pattern, a power pattern, and/or a ground pattern. Each of the patterns may have a line, pad, and/or plane shape.

Each of the first and second conductor patterns 121 and 122 may include an electroless plating layer (e.g., chemical copper) and an electrolytic plating layer (e.g., electrolytic copper). The first and second conductor patterns 121 and 122 may include a sputtering layer instead of an electroless plating layer, and if necessary, the first and second conductor patterns 121 and 122 may include both the sputtering layer and the electroless plating layer. For example, the first conductor pattern 121 may include a first seed layer 121a and a first metal layer 121b, and the second conductor pattern 122 may include a second seed layer 122a and a second metal layer 122b. Each of the first and second seed layers 121a and 122a may be an electroless plating layer and/or a sputtering layer, and may include, for example, a copper (Cu) layer or a titanium (Ti) layer/copper (Cu) layer, respectively. Each of the first and second metal layers 121b and 122b may be an electrolytic plating layer, and may include, for example, a copper (Cu) layer. The first and second insulating films 151 and 152 may not be formed on lower surfaces of the first and second conductor patterns 121 and 122, respectively, but the present disclosure is not limited thereto.

The via pattern 131 may include a metal material. The metal material may include copper (Cu), aluminum (Al), silver (Ag), tin (Sn), gold (Au), nickel (Ni), lead (Pb), titanium (Ti), and/or alloys thereof. The via pattern 131 may include, preferably, copper (Cu), but is not limited thereto. The via pattern 131 may include a signal via, a power via, and/or a ground via. The via pattern 131 may have a tapered shape in which a width of an upper portion thereof is wider than a width of a lower portion thereof on the cross-section, but the present disclosure is not limited thereto. The via pattern 131 may include an electroless plating layer (e.g., chemical copper) and an electrolytic plating layer (e.g., electrolytic copper). The via pattern 131 may include a sputtering layer instead of an electroless plating layer, and if necessary, the via pattern 131 may include both the sputtering layer and the electroless plating layer. For example, the via pattern 131 may include a third seed layer 131a and a third metal layer 131b. The third seed layer 131a may be an electroless plating layer and/or a sputtering layer, and may include, for example, a copper (Cu) layer or a titanium (Ti) layer/copper (Cu) layer. The third metal layer 131b may be an electrolytic plating layer, and may include, for example, a copper (Cu) layer. The via pattern 131 may be integrated with the second conductor pattern 122, and for example, the second and third seed layers 122a and 131a may be integrally connected to each other, and the second and third metal layers 122b and 131b may be integrally connected to each other.

Each of the first and second insulating films 151 and 152 may include an insulating material. The insulating material may be an organic insulating material and/or an inorganic insulating material. For example, each of the first and second insulating films 151 and 152 may be a combination of an inorganic layer and an organic layer. Each of the inorganic layer and the organic layer may be a thin film coating layer that may be formed by sputtering, Chemical Vapor Deposition (CVD), Plasma Enhanced Chemical Vapor Deposition (PECVD), Atomic Layer Deposition (ALD), or the like. From the viewpoint of high step coverage and thickness uniformity, the first and second insulating films 151 and 152 may be formed, preferably, by ALD, but the present disclosure is not limited thereto. The inorganic layer may include, for example, Al₂O₃, TiO₂, TaO₂, and/or SiNₓ, and may include, preferably, Al₂O₃, but the present disclosure is not limited thereto. The organic layer may include, for example, an amino silane compound and/or an imidazole silane compound, and may include, preferably, an amino silane compound, for example, 3-Aminopropyltriethoxysilane (APTES), but the present disclosure is not limited thereto. If necessary, the second insulating film 152 may be omitted, but the present disclosure is not limited thereto.

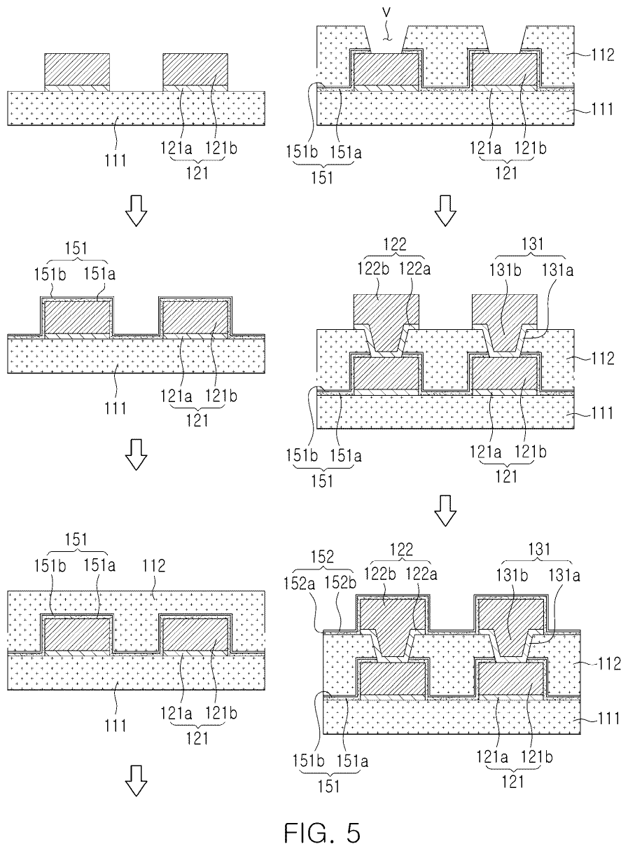

FIG. 5 is a schematic process cross-sectional view according to an example of manufacturing the printed circuit board of FIG. 3.

Referring to FIG. 5, first, a first conductor pattern 121 may be formed on an upper surface of a first insulating layer 111. The first insulating layer 111 may be formed by laminating ABF, or the like. The first conductor pattern 121 may be formed in a circuit process such as Tenting (TT), Additive Process (AP), Semi Additive Process (SAP), Modified Semi Additive Process (MSAP). Next, a first insulating film 151 continuously and conformally covering an upper surface of the first insulating layer 111 and a surface of the first conductor pattern 121 may be formed. The first insulating film 151 may be formed in a dry pretreatment process such as Chemical Vapor Deposition (CVD), Plasma Enhanced Chemical Vapor Deposition (PECVD), or Atomic Layer Deposition (ALD). For example, a bilayer structure of a first inorganic layer 151a and a first organic layer 151b may be continuously formed through a deposition and/or coating process in a vacuum chamber. Next, a second insulating layer 112 embedding the first conductor pattern 121 and the first insulating film 151 may be formed on the first insulating layer 111. The second insulating layer 112 may be formed by laminating ABF, or the like. Next, a via hole v penetrating through the second insulating layer 112 and the first insulating film 151 may be formed. The via hole v may be formed with a laser drill, or the like. Next, a via pattern 131 filling the via hole v and a second conductor pattern 122 disposed on an upper surface of the second insulating layer 112 may be formed. The via pattern 131 and the second conductor pattern 122 may be formed in a circuit process such as Tenting (TT), Additive Process (AP), Semi Additive Process (SAP), or Modified Semi Additive Process (MSAP). Next, a second insulating film 152 conformally and continuously covering the upper surface of the second insulating layer 112 and the surface of the second conductor pattern 122 may be formed. The second insulating film 152 may be formed in a dry pretreatment process such as Chemical Vapor Deposition (CVD), Plasma Enhanced Chemical Vapor Deposition (PECVD), or Atomic Layer Deposition (ALD). For example, a bilayer structure of a second inorganic layer 152a and a second organic layer 152b may be formed continuously through a deposition and/or coating process in a vacuum chamber.

A printed circuit board 100A according to the above-described example embodiment may be manufactured through a series of processes. Other details may be substantially the same as those described above, and therefore, overlapping descriptions thereof will be omitted.

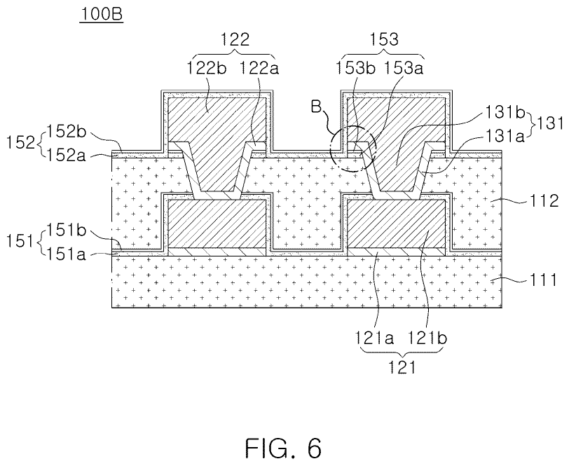

FIG. 6 is a cross-sectional view schematically illustrating another example of a printed circuit board.

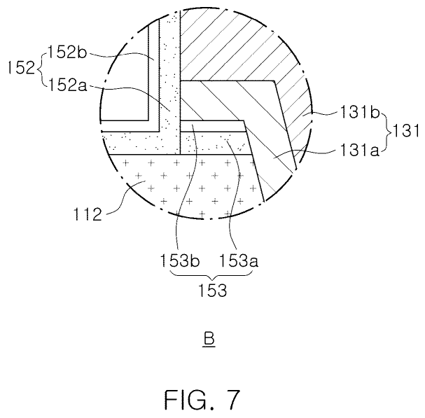

FIG. 7 is a schematic enlarged cross-sectional view of region B of the printed circuit board of FIG. 6.

Referring to the drawings, a printed circuit board 100B according to another example embodiment may further include a third insulating film 153 at least partially disposed between an upper surface (second surface) of the second insulating layer 112 and a lower surface (second surface) of the second conductor pattern 122, in the printed circuit board 100A according to the above-described example embodiment. The via pattern 131 may further penetrate through the third insulating film 153. An inner side surface of the third insulating film 153 may be in contact with the via pattern 131, and an outer side surface of the third insulating film 153 may be in contact with the second insulating film 152. The third insulating film 153 may include a third inorganic layer 153a and/or a third organic layer 153b similar to the first and second insulating films 151 and 152. Between the second insulating layer 112 and the second conductor pattern 122, the third inorganic layer 153a may be in contact with the second insulating layer 112, and the third organic layer 153b may be in contact with the second conductor pattern 122. More specific details about the third inorganic layer 153a and the third organic layer 153a may be substantially the same as described in the first and second inorganic layers 152a and the first and second organic layers 152b described above. Through the third insulating film 153, the adhesion between the second insulating layer 112 and the second conductor pattern 122 may be further improved, and interlayer short circuits due to foreign substances/damage/scratches, or the like, may be more effectively improved.

Other details may be substantially the same as described above, and therefore, redundant descriptions thereof will be omitted.

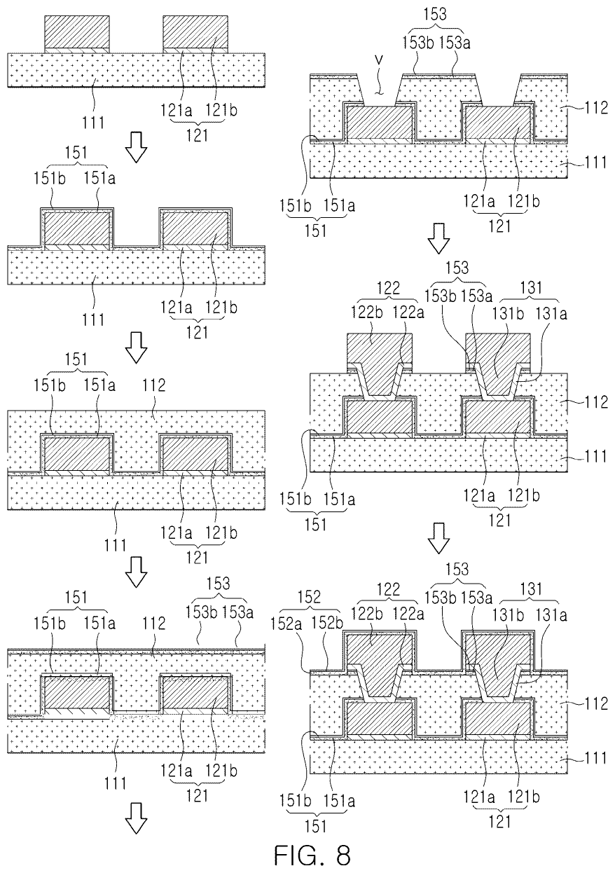

FIG. 8 is a schematic process cross-sectional view according to an example of manufacturing the printed circuit board of FIG. 6.

Referring to FIG. 8, first, a first conductor pattern 121 may be formed on an upper surface of a first insulating layer 111. The first insulating layer 111 may be formed by laminating ABF, or the like. The first conductor pattern 121 may be formed in a circuit process such as Tenting (TT), Additive Process (AP), Semi Additive Process (SAP), Modified Semi Additive Process (MSAP). Next, a first insulating film 151 continuously and conformally covering an upper surface of the first insulating layer 111 and a surface of the first conductor pattern 121 may be formed. The first insulating film 151 may be formed in a dry pretreatment process such as Chemical Vapor Deposition (CVD), Plasma Enhanced Chemical Vapor Deposition (PECVD), or Atomic Layer Deposition (ALD).

For example, a bilayer structure of a first inorganic layer 151a and a first organic layer 151b may be continuously formed through a deposition and/or coating process in a vacuum chamber. Next, a second insulating layer 112 embedding the first conductor pattern 121 and the first insulating film 151 may be formed on the first insulating layer 111. The second insulating layer 112 may be formed by laminating ABF, or the like. Next, a third insulating film 153 continuously and conformally covering an upper surface of the second insulating layer 112 may be formed. The third insulating film 153 may be formed in a dry pretreatment process such as Chemical Vapor Deposition (CVD), Plasma Enhanced Chemical Vapor Deposition (PECVD), or Atomic Layer Deposition (ALD). For example, a bilayer structure of a third inorganic layer 153a and a third organic layer 153b may be continuously formed through a deposition and/or coating process in a vacuum chamber. Next, a via hole v penetrating through the second insulating layer 112, the first insulating film 151 and the third insulating film 153 may be formed. The via hole v may be formed by a laser drill, or the like. Next, a via pattern 131 filling the via hole v and a second conductor pattern 122 disposed on an upper surface of the third insulating film 153 may be formed. The via pattern 131 and the second conductor pattern 122 may be formed in a circuit process such as Tenting (TT), Additive Process (AP), Semi Additive Process (SAP), or Modified Semi Additive Process (MSAP). If necessary, the third insulating film 153 remaining in a region other than a region in which the second conductor pattern 122 is formed on the upper surface of the second insulating layer 112 may be removed. Next, a second insulating film 152 conformally and continuously covering the upper surface of the second insulating layer 112 and the surface of the second conductor pattern 122 may be formed. The second insulating film 152 may be formed in a dry pretreatment process such as Chemical Vapor Deposition (CVD), Plasma Enhanced Chemical Vapor Deposition (PECVD), or Atomic Layer Deposition (ALD). For example, a bilayer structure of a second inorganic layer 152a and a second organic layer 152b may be formed continuously through a deposition and/or coating process in a vacuum chamber.

A printed circuit board 100B according to another example embodiment described above may be manufactured through a series of processes. Other details may be substantially the same as described above, and therefore, redundant descriptions thereof will be omitted.

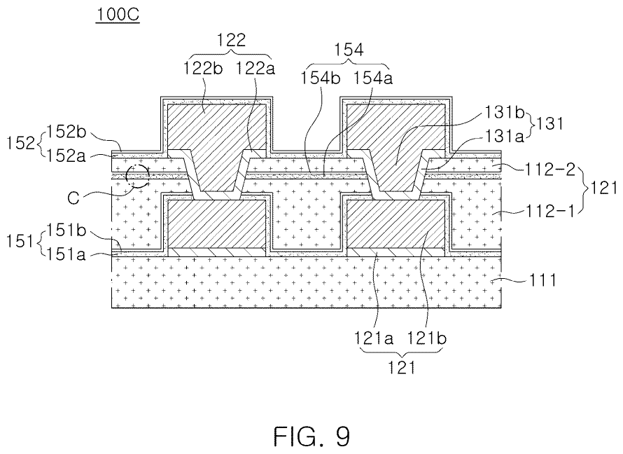

FIG. 9 is a cross-sectional view schematically illustrating another example of a printed circuit board.

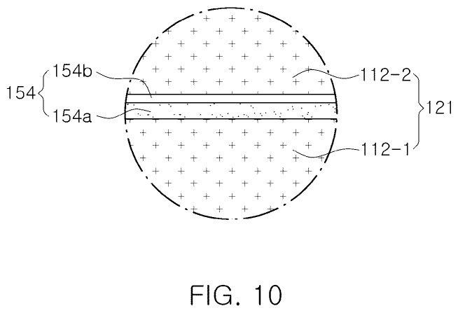

FIG. 10 is a schematic enlarged cross-sectional view of region C of the printed circuit board of FIG. 9.

Referring to the drawings, a printed circuit board 100C according to another example embodiment may further include a fourth insulating film 154 disposed in the second insulating layer 112 and configured to divide the second insulating layer 112 into a plurality of regions 112-1 and 112-2, for example, a first region 112-1 adjacent to the first conductor pattern 121 and a second region 112-2 adjacent to the second conductor pattern 122, in the printed circuit board 100A according to the above-described example embodiment. The via pattern 131 may further penetrate through the fourth insulating film 154. An inner side surface of the fourth insulating film 154 may be in contact with the via pattern 131. The fourth insulating film 154 may be thinner than each of the first and second regions 112-1 and 112-2. When a thickness thereof is not constant, a size relationship may be compared using an average thickness. Here, the average thickness may be an average of thickness values measured at five arbitrary points. For example, an average thickness of the fourth insulating film 154 on the cross-section may be thinner than an average thickness of each of the first and second regions 112-1 and 112-2. The fourth insulating film 154 may include a fourth inorganic layer 154a and/or a fourth organic layer 154b, similar to the first and second insulating films 151 and 152. Between the first and second regions 112-1 and 112-2, the fourth inorganic layer 154a may be in contact with the first region 112-1, and the fourth organic layer 154b may be in contact with the second region 112-2. More specific details about the fourth inorganic layer 154a and the fourth organic layer 154a may be substantially the same as those described above for the first and second inorganic layers 152a and the first and second organic layers 152b. Even when the second insulating layer 112 is formed of a plurality of layers through the fourth insulating film 154, excellent adhesion may be achieved, and interlayer short circuits due to foreign substance/damage/scratches, or the like, may be more effectively improved. For example, defects due to Foreign Material (FM), dents, voids, and the like, may be improved.

Other details may be substantially the same as described above, and therefore, redundant description thereof will be omitted.

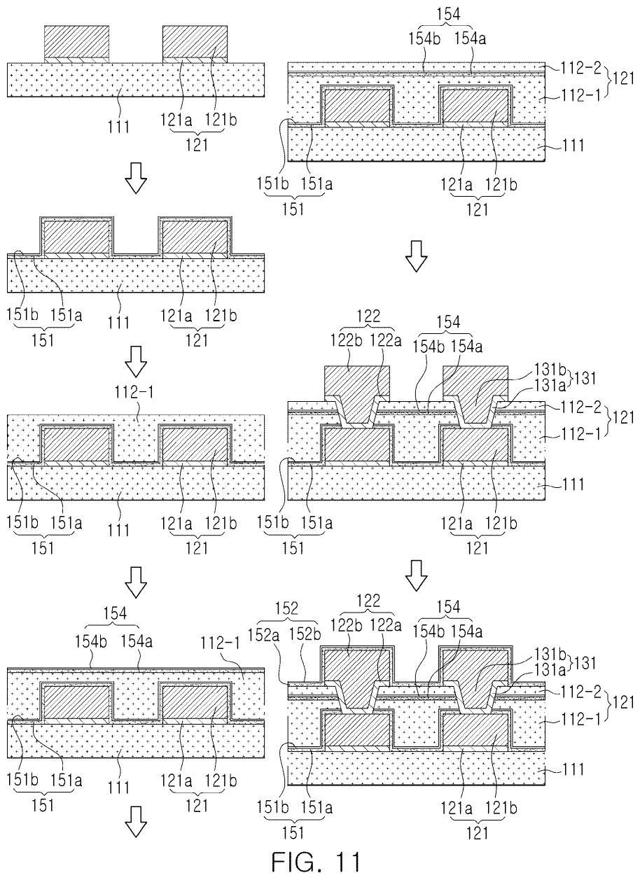

FIG. 11 is a schematic process cross-sectional view according to an example of manufacturing the printed circuit board of FIG. 9.

Referring to FIG. 11, first, a first conductor pattern 121 may be formed on an upper surface of a first insulating layer 111. The first insulating layer 111 may be formed by laminating ABF or the like. The first conductor pattern 121 may be formed in a circuit process such as Tenting (TT), Additive Process (AP), Semi Additive Process (SAP), or Modified Semi Additive Process (MSAP). Next, a first insulating film 151 conformally and continuously covering an upper surface of first insulating layer 111 and surface of the first conductor pattern 121 may be formed. The first insulating film 151 may be formed in a dry pretreatment process such as Chemical Vapor Deposition (CVD), Plasma Enhanced Chemical Vapor Deposition (PECVD), or Atomic Layer Deposition (ALD). For example, a bilayer structure of a first inorganic layer 151a and a first organic layer 151b may be continuously formed through a deposition and/or coating process in a vacuum chamber. Next, a second-first insulating layer 112-1 embedding the first conductor pattern 121 and the first insulating film 151 may be formed on the first insulating layer 111. The second-first insulating layer 112-1 may correspond to the first region 112-1 described above. The second-first insulating layer 112-1 may be formed by laminating ABF or the like. Next, a fourth insulating film 154 continuously and conformally covering an upper surface of the second-first insulating layer 112-1 may be formed. The fourth insulating film 154 may be formed in a dry pretreatment process such as Chemical Vapor Deposition (CVD), Plasma Enhanced Chemical Vapor Deposition (PECVD), or Atomic Layer Deposition (ALD). For example, a bilayer structure of a fourth inorganic layer 154a and a fourth organic layer 154b may be continuously formed through a deposition and/or coating process in a vacuum chamber. Next, a second-second insulating layer 112-2 may be formed on the fourth insulating film 154. The second-second insulating layer 112-2 may correspond to the second region 112-2 described above. The second-second insulating layer 112-2 may be formed by laminating ABF, or the like.

Next, a via hole v penetrating through the second-first insulating layer 112-1, the second-second insulating layer 112-2, the first insulating film 151, and the fourth insulating film 154 may be formed. The via hole v may be formed by a laser drill or the like. Next, a via pattern 131 filling the via hole v and a second conductor pattern 122 disposed on an upper surface of the second-second insulating layer 112-2 may be formed. The via pattern 131 and the second conductor pattern 122 may be formed in a circuit process such as Tenting (TT), Additive Process (AP), Semi Additive Process (SAP), or Modified Semi Additive Process (MSAP). Next, a second insulating film 152 continuously and conformally covering the upper surface of the second-second insulating layer 112-2 and a surface of the second conductor pattern 122 may be formed. The second insulating film 152 may be formed in a dry pretreatment process such as Chemical Vapor Deposition (CVD), Plasma Enhanced Chemical Vapor Deposition (PECVD), or Atomic Layer Deposition (ALD). For example, a bilayer structure of a second inorganic layer 152a and a second organic layer 152b may be continuously formed through a deposition and/or coating process in a vacuum chamber.

A printed circuit board 100C according to another example embodiment described above may be manufactured through a series of processes. Other details may be substantially the same as described above, and therefore, a redundant description thereof will be omitted.

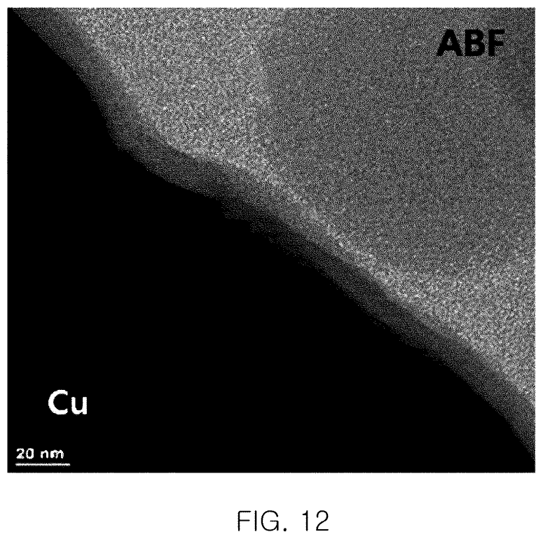

FIG. 12 is a cross-sectional image schematically illustrating a layer structure of an insulating film formed between a conductor pattern and an insulating material.

Referring to FIG. 12, an insulating film having a bilayer structure, a mixed structure of a metal oxide film and an organic film, may be disposed between a conductor pattern (e.g., Cu) and an insulating material (e.g., ABF). The insulating film may have a thickness of several to several tens of nanometers. The insulating film may be applied as at least one of the first to fourth insulating films described above. Through the arrangement of the insulating film, adhesion between the conductor pattern and the insulating material may be secured, and signal loss may be improved through a non-roughness surface treatment, and interlayer short circuits or migration due to foreign substances/damages/scratches, or the like, may be improved.

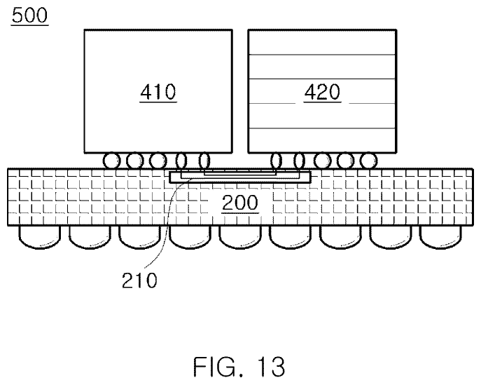

FIG. 13 is a cross-sectional view schematically illustrating an example of a semiconductor package.

Referring to FIG. 13, a semiconductor package 500 according to an example embodiment may include a package substrate 200 and first and second semiconductor chips 410 and 420 mounted on the package substrate 200. The package substrate 200 may include a bridge substrate 210 including fine wirings interconnecting the first and second semiconductor chips 410 and 420. The bridge substrate 210 may include at least one of the printed circuit boards 100A, 100B and 100C described above as an internal structure. For example, the bridge substrate 210 may have a wiring structure including a plurality of insulating layers, a plurality of wiring layers respectively disposed on or in the plurality of insulating layers, and a plurality of via layers respectively penetrating through at least one of the plurality of insulating layers. In this case, the plurality of insulating layers may include the first and/or second insulating layers described above, and the plurality of wiring layers may include the first and/or second conductor patterns described above, and the plurality of wiring layers may include the via patterns described above, and may further include the first, second, third and/or fourth insulating films described above. The package substrate 200 may be a typical multilayer printed circuit board, and a specific structure thereof is not particularly limited. If necessary, an internal structure of the package substrate 200 may include at least one of the printed circuit boards 100A, 100B and 100C described above. The first and second semiconductor chips 410 and 420 may be memory chips, application processor chips, and/or logic chips, respectively. The first and second semiconductor chips 410 and 420 may be the same type of chips or different types of chips.

Other details are substantially the same as described above, and redundant description thereof will be omitted.

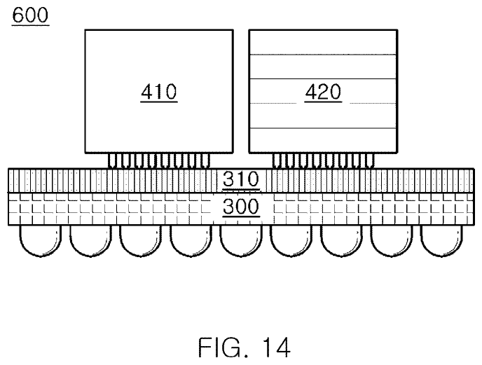

FIG. 14 is a cross-sectional view schematically illustrating another example of a semiconductor package.

Referring to FIG. 14, a semiconductor package 600 according to another example embodiment may include a package substrate 300 and first and second semiconductor chips 410 and 420 mounted on the package substrate 300. A fine wiring layer 310 including fine wirings interconnecting the first and second semiconductor chips 410 and 420 may be disposed on an outermost side of the package substrate 300. The fine wiring layer 310 may include at least one of the printed circuit boards 100A, 100B and 100C described above. For example, the fine wiring layer 310 may have a wiring structure including a plurality of insulating layers, a plurality of wiring layers respectively disposed on or in the plurality of insulating layers, and a plurality of via layers respectively penetrating through at least one of the plurality of insulating layers. In this case, the plurality of insulating layers may include the first and/or second insulating layers described above, the plurality of wiring layers may include the first and/or second conductor patterns described above, the plurality of wiring layers may include the via patterns described above, and may further include the first, second, third and/or fourth insulating films described above. The package substrate 300 may be a typical multilayer printed circuit board, and a specific structure thereof is not particularly limited. If necessary, an internal structure of the package substrate 300 may include at least one of the printed circuit boards 100A, 100B and 100C described above. The first and second semiconductor chips 410 and 420 may be memory chips, application processor chips, and/or logic chips, respectively. The first and second semiconductor chips 410 and 420 may be the same type of chips or different types of chips.

Other than that, the other contents are substantially the same as described above, and redundant descriptions thereof will be omitted.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of partially filling, and may also include a case of approximately filling. Additionally, the expression ‘surrounding’ may include not only a case of completely surrounding but also a case of partially surrounding and a case of approximately surrounding. Additionally, exposing may include partial exposing as well as a case of complete exposing, and exposure may refer to exposure from embedding a corresponding component.

In the present disclosure, determination may be performed by including process errors, positional deviations, errors at the time of measurement, which may occur substantially in a manufacturing process. For example, substantially constant thickness may include not only a case in which the thickness is completely constant, but also a case in which the thickness is approximately constant. Furthermore, being substantially coplanar may include not only a case in which elements are completely on the same plane, but also a case in which the elements are approximately on the same plane.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points. Other methods and/or tools appreciated by one of ordinary skill in the art, even if not described in the present disclosure, may also be used.

The expression ‘example embodiment used in the present disclosure’ does not mean the same embodiment, and is provided to emphasize and explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a first conductor pattern;
a first insulating film covering at least a portion of the first conductor pattern and conforming to a shape of a surface of the first conductor pattern; and
an insulating layer disposed on the first insulating film,
wherein the first insulating film includes a first inorganic layer and a first organic layer.

2. The printed circuit board according to claim 1,
wherein on the surface of the first conductor pattern, the first inorganic layer is in contact with the first conductor pattern, and the first organic layer is in contact with the insulating layer.

3. The printed circuit board according to claim 1,
wherein the first inorganic layer is thicker than the first organic layer.

4. The printed circuit board according to claim 3,
wherein the first inorganic layer has a thickness of 1 nm to 50 nm, and
the first organic layer has a thickness of 0.1 nm to 10 nm.

5. The printed circuit board according to claim 1,
wherein the first inorganic layer includes a metal oxide, a nitride, or both, and
the first organic layer includes a silane compound.

6. The printed circuit board according to claim 5,
wherein the metal oxide is one or more selected from Al₂O₃, TiO₂, and TaO₂,
the nitride includes SiNₓ, and
the silane compound is one or more selected from an amino silane compound and an imidazole silane compound.

7. The printed circuit board according to claim 6,
wherein the first inorganic layer includes the metal oxide, and the metal oxide includes Al₂O₃.

8. The printed circuit board according to claim 6,
wherein the first organic layer includes the amino silane compound, and the amino silane compound includes 3-aminopropyltriethoxysilane.

9. The printed circuit board according to claim 6,
wherein the silane compound includes the imidazole silane compound.

10. The printed circuit board according to claim 1,
wherein the first insulating film extends onto a first surface of the insulating layer.

11. The printed circuit board according to claim 10, comprising a plurality of the first conductor pattern,
the first insulating film covers at least a portion of each of the plurality of the first conductor pattern and conforms to a shape of a surface of each of the plurality of the first conductor pattern, and
the first insulating film is continuously disposed on the first surface of the insulating layer between the plurality of the first conductor pattern.

12. The printed circuit board according to claim 1, further comprising:
a second conductor pattern disposed on the insulating layer; and
a via pattern penetrating through the insulating layer and the first insulating film to connect the first and second conductor patterns to each other.

13. The printed circuit board according to claim 12, wherein the first conductor pattern includes a first seed layer and a first metal layer,
the second conductor pattern includes a second seed layer and a second metal layer,
the via pattern includes a third seed layer and a third metal layer,
the second and third seed layers are integrally connected to each other,
the second and third metal layers are integrally connected to each other.

14. The printed circuit board according to claim 12, further comprising:
a second insulating film covering at least a portion of the second conductor pattern and conforming to a shape of a first surface of the second conductor pattern,
wherein the second insulating film extends onto a second surface of the insulating layer, and
the second insulating film includes one or more of a second inorganic layer and a second organic layer.

15. The printed circuit board according to claim 12, further comprising:
a third insulating film at least partially disposed between a second surface of the insulating layer and a second surface of the second conductor pattern,
wherein the via pattern further penetrates through the third insulating film, and
the third insulating film includes one or more of a third inorganic layer and a third organic layer.

16. The printed circuit board according to claim 12, further comprising:
a fourth insulating film disposed in the insulating layer,
wherein the fourth insulating film divides the insulating layer into a first region adjacent to the first conductor pattern and a second region adjacent to the second conductor pattern,
the via pattern further penetrates through the fourth insulating film, and
the fourth insulating film includes one or more of a fourth inorganic layer and a fourth organic layer.

17. The printed circuit board according to claim 1, wherein the insulating layer includes an Ajinomoto Build-up Film (ABF).

18. A printed circuit board, comprising:
a first insulating layer;
a first conductor pattern embedded in a first side of the first insulating layer, wherein at least a portion of a first surface of the first conductor pattern is exposed from a first surface of the first insulating layer;
a first insulating film covering at least a portion of each of a second surface and a side surface of the first conductor pattern and conforming to a shape of the first conductor pattern, and extending onto the first surface of the first insulating layer;
a second insulating layer disposed on a second surface of the first insulating layer;
a second insulating film disposed between the first and second insulating layers and having a thickness thinner than each of the first and second insulating layers; and
a second conductor pattern disposed on a first surface of the second insulating layer.

19. The printed circuit board according to claim 18, further comprising:
a via pattern penetrating through the first and second insulating layers and the first and second insulating films to connect the first and second conductor patterns to each other.
